(19) United States
(12) Patent Application Publication
(10) Pub. No.: US 2008/0112128 A1
(43) Pub. Date: May 15, 2008

(54) Cooling Methods and Apparatus

(75) Inventor: Michael James Holland, Norfolk (GB)

Correspondence Address: HARNESS, DICKEY & PIERCE, P.L.C., P.O. BOX 828, BLOOMFIELD HILLS, MI, 48303, US

(73) Assignee: TROX (UK) LIMITED, Norfolk (GB)

(21) Appl. No.: 11/663,493

(22) PCT Filed: Sep. 22, 2005
(86) PCT No.: PCT/GB05/03648

§ 371 Date: Aug. 28, 2007

(30) Foreign Application Priority Data
Sep. 23, 2004 (GB) 0421232.0

(51) Int. Cl. H05K 5/00; F25B 1/00

(52) U.S. Cl. 361/687; 312/236; 62/498

(57) ABSTRACT

Computer cooling equipment for computer equipment comprises: a primary heat transfer circuit; a secondary heat transfer circuit containing a secondary heat transfer fluid, a secondary condenser cooled by the primary heat transfer circuit and a secondary evaporator for cooling the computer equipment; and is characterised in that the secondary heat transfer fluid is a volatile fluid. The secondary heat transfer fluid may be carbon dioxide. The cooling system is of particular use in power hungry applications such as cooling of computer servers, particularly of blade servers as it can produce a heat load dissipation of up to 100 kW, compared to 10 kW or less using conventional systems. Heat exchange cabinets, air conditioning systems and building elements using a secondary heat transfer fluid which is a volatile fluid are also disclosed.

This invention relates to cooling methods and apparatus. In particular, although not exclusively, this application relates to cooling methods and apparatus in the field of information technology, such as cooling for information technology servers.

Traditionally IT servers have been cooled using combination water/air systems, water being the primary coolant and air being the secondary coolant. Cooled air is pumped by fans into the floor void beneath the equipment and released into the room through grilles sited appropriately around the floor. Fans in the cabinets and on the racks themselves draw airflow over the heated equipment and heat transfer takes place. Typical loads of 5 kW to 8 kW per 900 mm×600 mm×1800 mm equipment cabinet have been reached using these systems; generally the load produced by the cabinet depends on the processing power of the equipment contained therein.

Air is electrically benign, and inherently safe, which makes it highly attractive to building systems engineers. Air has been used as the primary heat transfer material since the cooling of IT equipment began, and the industry is geared to the exclusive use of air-based systems.

However, as transistors have become smaller, and chip capacity has grown, the power dissipation requirements of information technology or computing equipment has grown. This has been greatly exacerbated recently by the development of blade servers which sit vertically rather than horizontally in cabinets, and therefore can be packed in at a far higher density.

These servers can, even with current technology, dissipate of the order of 18 kW per cabinet. With current equipment, in as much as such loads can be cooled at all, this requires the use of extremely large volumes of air, which is energy inefficient, and leads to large installations which are noisy and unpleasant to work in, due to excessive room air velocities making the space almost inhospitable.

In order to cool these large loads effectively, the IT server industry has had to increase the space between adjacent cabinets, increasing the volume of air available, and the air flow around each cabinet, and to limit the number of servers in each cabinet. This, however, leads to larger installations and prevents full advantage being taken of advances in server technology.

According to this invention there is provided computer cooling equipment comprising: a circuit for a heat transfer fluid containing a condenser; and an evaporator; characterised in that the heat transfer fluid is a volatile fluid.

This invention provides the realisation that it is possible to use cooling media other than air in a secondary cooling circuit for use in high heat gain applications of IT equipment. Furthermore, it realizes that volatile fluids, such as carbon dioxide, may be electrically benign and so may be used safely in such applications despite the very high pressures, for carbon dioxide over 50 Bar, which are needed to obtain adequate cooling.

Volatile fluids, such as carbon dioxide, provide a very energy efficient means of providing cooling, and so can cool cabinets having a much higher heat load. They are also provide the opportunity to save energy, especially when compared to propelling large volumes of air through the equipment, and they only require relatively narrow diameter pipes.

Conveniently the secondary circuit is operable to dissipate a heat transfer load of greater than 20 kW, preferably greater than 30 kW, and dissipation of loads greater than 50 kW, 70 kW, or even 100 kW are possible.

The secondary evaporator may be positioned on any of the sides, the top or the bottom of a computer cabinet containing computer equipment. The secondary evaporator may be positioned on more than one, or indeed all sides of the computer cabinet. It is even possible that the secondary evaporator is positioned inside a computer cabinet containing computer equipment.

The secondary evaporator may be contained in a heat exchange cabinet. The heat exchange cabinet may comprise a shroud positioned at its air inlet such that incoming air is drawn from an adjacent side of the computer cabinet to that on which the heat exchange cabinet is disposed. Additionally, or alternatively, the heat exchange cabinet may comprise a shroud positioned at its air outlet such that outgoing air is expelled to an adjacent side of the computer cabinet to that on which the heat exchange cabinet is disposed.

The cabinet may comprise a plurality of fans to draw air through the cabinet.

The cabinet may comprise a perforated panel sandwiched between the secondary evaporator and the equipment cabinet.

The secondary circuit may be operable at up to 25 Bar. Conveniently the secondary circuit is operable at up to 50 Bar. Preferably the secondary circuit is operable at up to 75 Bar.

The secondary evaporator may comprise a heat exchanger constructed of a copper and aluminium finned coil. The coil may be pressure tested at or above 100 Bar. The secondary evaporator may comprise interlaced coils with dual pipework.

Preferably the volatile fluid is carbon dioxide. The temperature of the carbon dioxide received at the secondary evaporator may be in the region of 0° C. to 30° C. and conveniently is in the region of 12° C. to 16° C., preferably being substantially 14° C.

Such computer cooling equipment is of particular use for a computer server especially a blade server.

Secondary circuits, secondary evaporators and heat exchange cabinets are also provided by the invention for use in the cooling systems outlined above.

This invention further provides a computer installation comprising a plurality of computer equipment contained in a plurality of computer cabinets and computer cooling equipment as described above.

According to a second aspect of this invention there is provided a method of cooling computer equipment comprising: circulating a fluid through a secondary heat transfer circuit to a heat exchanger which is disposed adjacent to the computer equipment, characterised in that the fluid is a volatile fluid. Preferably the fluid is carbon dioxide.

According to a third aspect of this invention there is provided a housing for computer equipment comprising an outer layer and an inner layer characterised in that a heat exchanger is disposed between the outer layer and the inner layer.

The housing may comprise a heat exchanger as described above. The housing may have a top, sides, a bottom, shelving and a front or rear door, one or more of which comprise the outer layer and the inner layer. The housing may have a cooling capacity of up to 20 kW per 900 mm long per 600 mm wide×1800 mm high cabinet. Conveniently the housing has a cooling capacity of up to 50 kW per 900 mm long per 600 mm wide×1800 mm high cabinet. The housing may comprise integral distribution pipework.

According to a fourth aspect of the invention there is provided an air conditioning unit comprising an air inlet, a heat exchanger, which forms part of a secondary heat transfer circuit and an air outlet comprising an induction jet having a plurality of nozzles characterised in that a heat transfer fluid flowing through the secondary circuit is a volatile fluid. Preferably the volatile fluid is carbon dioxide.

The air conditioning unit may be operable at a pressure of up to 50 Bar. Conveniently the air conditioning unit is operable at a pressure of up to 75 Bar.

The temperature of the volatile fluid may be in the region of 0° C. to 30° C., conveniently in the region of 12 to 16° C., preferably substantially 14° C.

The induction jet may operate at a static pressure of in the region of 30 to 200 Pa, conveniently in the region of 50 to 100 Pa, preferably substantially 80 Pa.

The heat exchanger may comprise copper pipework and aluminium fins. The heat exchanger may be operable to run with or without surface condensation.

The air conditioning unit may have a cooling capacity of up to 20 kW per jet. Preferably the air conditioning unit has a cooling capacity of up to 50 kW per jet.

According to a fifth aspect of the invention there is provided a building element comprising an air inlet, an air outlet, an air duct and a heat exchanger which forms part of a secondary heat transfer circuit characterised in that a heat transfer fluid flowing in the heat transfer circuit is a volatile fluid. Preferably the volatile fluid is carbon dioxide.

The air outlet may comprise an induction jet. The element may be an elongate beam.

The building element may be operable at a pressure of up to 50 Bar. Preferably the building element is operable at a pressure of up to 75 Bar.

The temperature of the volatile fluid may be in the region of 0 to 30° C., conveniently in the region of 12 to 16° C., preferably substantially 14° C.

The induction jet may operate at a static pressure of in the region of 30 to 200 Pa, conveniently in the region of 50 to 100 Pa, preferably substantially 80 Pa.

The heat exchanger may comprise copper pipework and aluminium fins.

The building element may comprise a housing for building services such as lighting, lighting control, public address/voice alarm speakers, passive infrared detectors, sprinklers, plasma screens, power cables etc.

The building element may have a capacity of up to 600 W/m, preferably substantially 600 W/m. Alternatively, if the air outlet comprises an induction jet, the building element may have a capacity of up to 800 W/m, preferably substantially 800 W/m.

According to a sixth aspect of the invention an air conditioning unit is provided comprising a heat exchanger which forms part of a secondary heat transfer circuit, and a plurality of fans, characterised in that a heat transfer fluid flowing through the secondary circuit is a volatile fluid. Preferably the volatile fluid is carbon dioxide.

The air conditioning unit may comprise a heater. The air conditioning unit may be operable at a pressure of up to 50 Bar. Preferably the air conditioning is operable at a pressure of up to 75 Bar.

The temperature of the volatile fluid may be in the region of 0 to 30° C., conveniently in the region of 12 to 16° C., preferably 14° C.

The heat exchanger may comprise copper pipework and aluminium fins. The heat exchanger may be operable to run with or without surface condensation.

The air conditioning unit may have a cooling capacity of up to 10 kW.

Embodiments of the invention will now be described, purely by way of example, with reference to the accompanying drawings, in which:

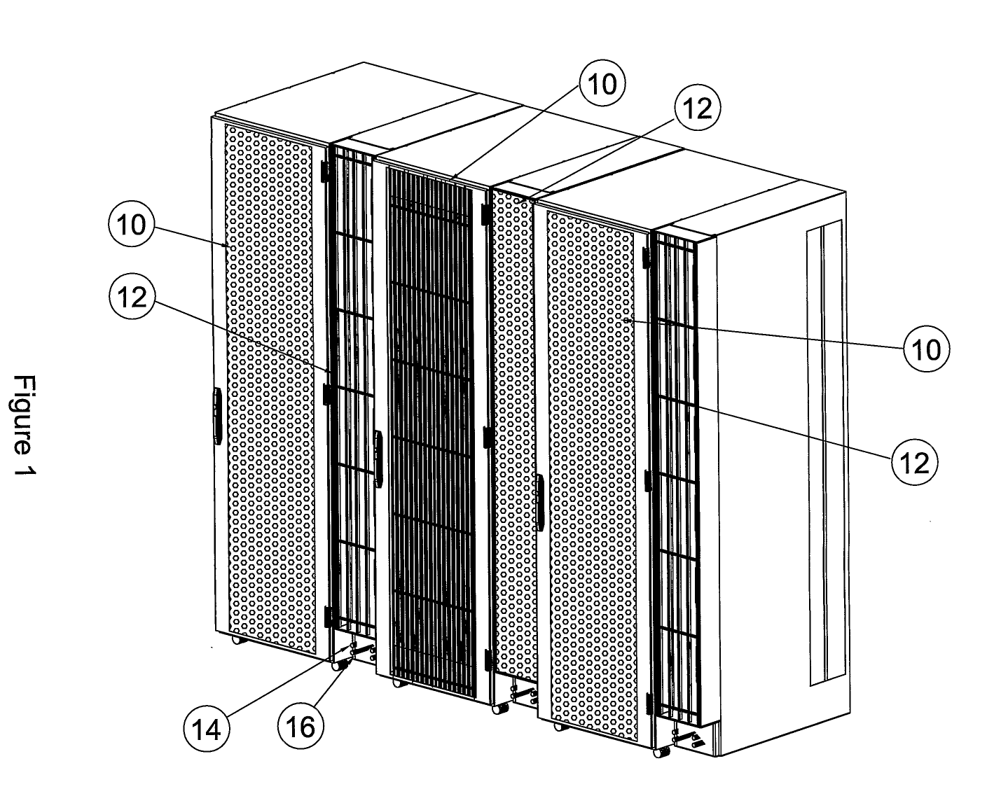

FIG. 1 shows schematically a perspective view of a set of cabinets containing blade servers having heat exchange cabinets between them;

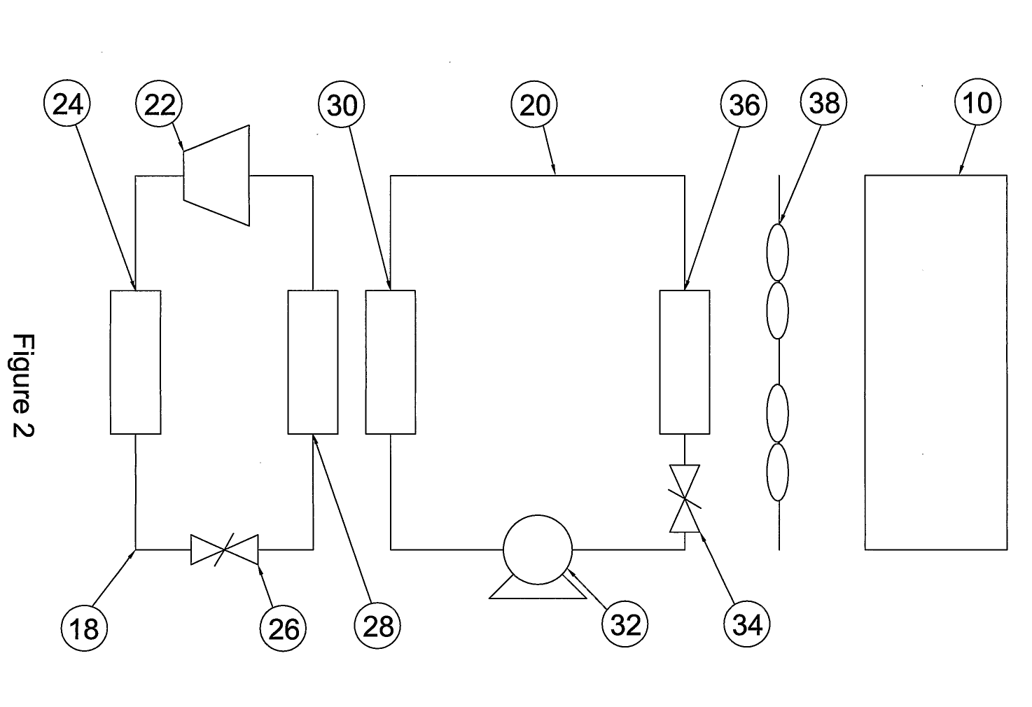

FIG. 2 shows schematically a flow diagram of an embodiment of Computer cooling equipment;

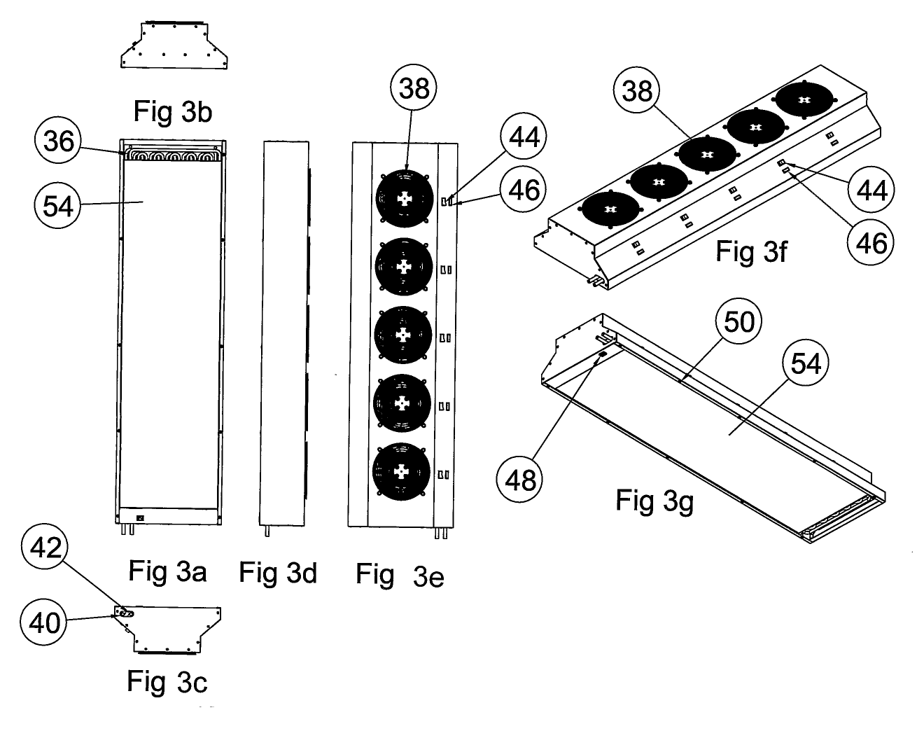

FIG. 3 shows schematically various views of the heat exchange cabinet of FIG. 2:

FIG. 3a shows a front view of the cabinet;

FIG. 3b shows a top view of the cabinet;

FIG. 3c shows a bottom view of the cabinet;

FIG. 3d shows a side view of the cabinet;

FIG. 3e shows a rear view of the cabinet;

FIG. 3f shows an upper perspective view of the cabinet; and

FIG. 3g shows a lower perspective view of the cabinet;

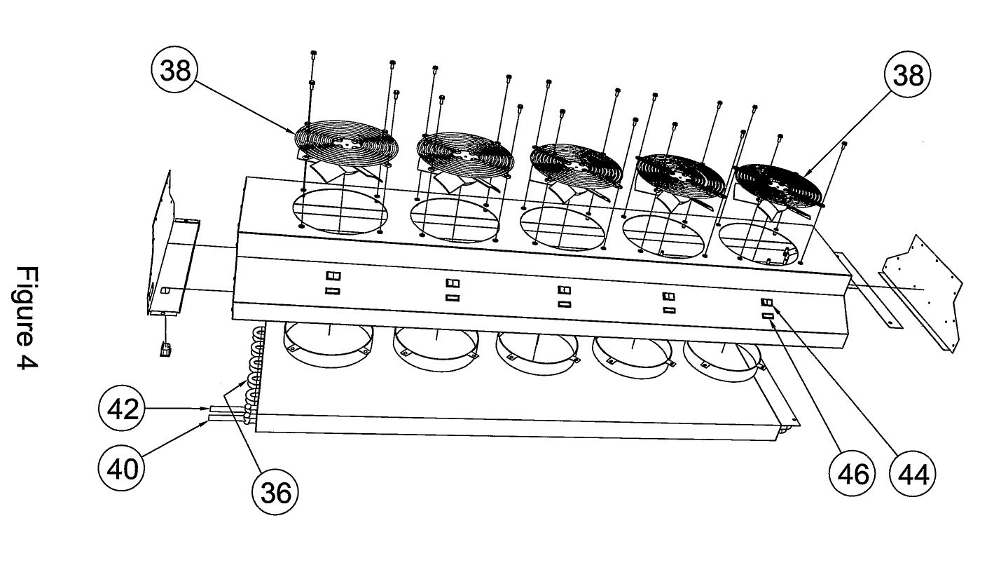

FIG. 4 shows schematically an exploded view of the cabinet of FIG. 3;

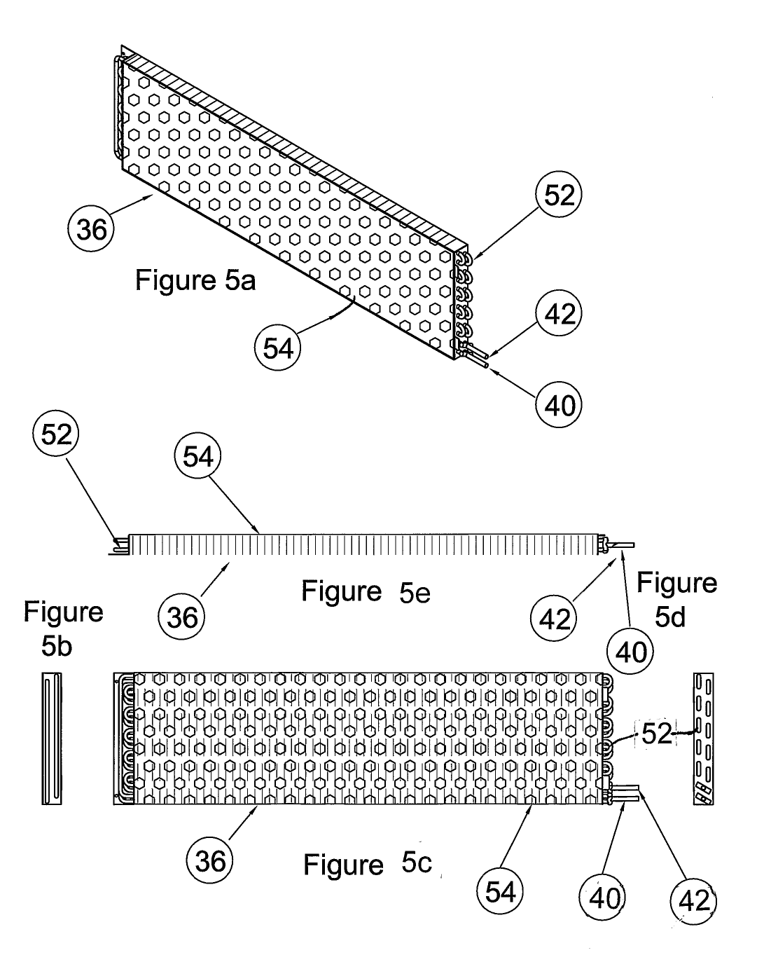

FIG. 5 shows schematically views of the heat exchanger of FIGS. 1 to 4:

FIG. 5a shows a perspective view;

FIG. 5b shows a top view;

FIG. 5c shows a front view;

FIG. 5d shows a bottom view; and

FIG. 5e shows a side view;

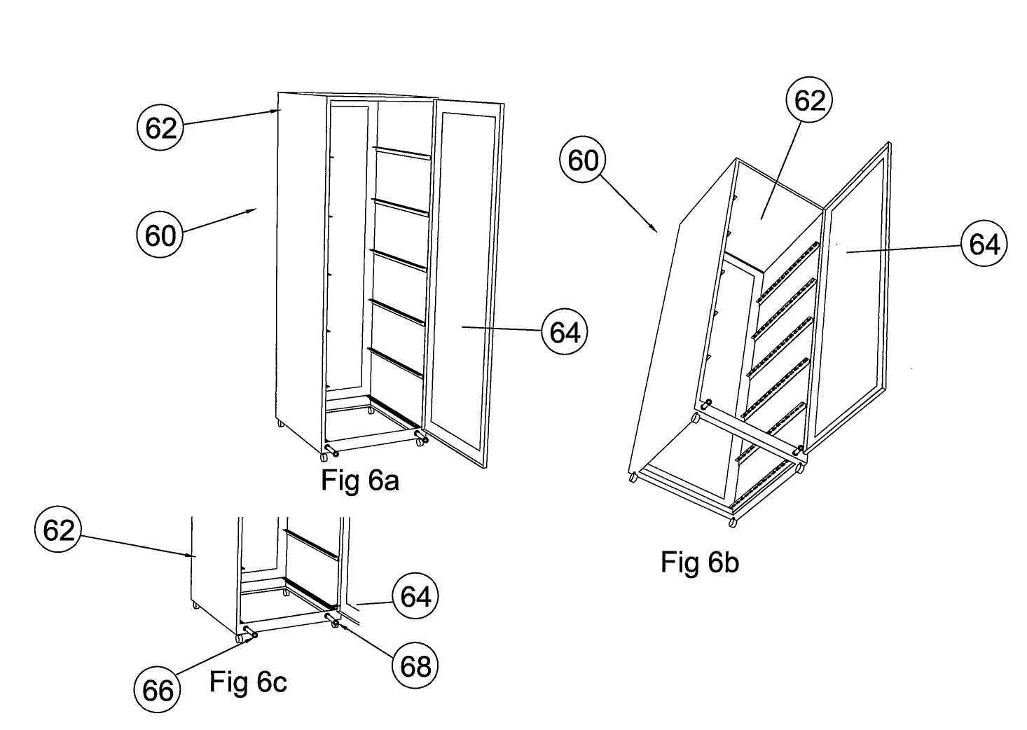

FIG. 6 shows schematically perspective views of a computer cabinet which is a further embodiment:

FIG. 6a shows an upper perspective view;

FIG. 6b shows a lower perspective view; and

FIG. 6c shows a detailed view of FIG. 6a;

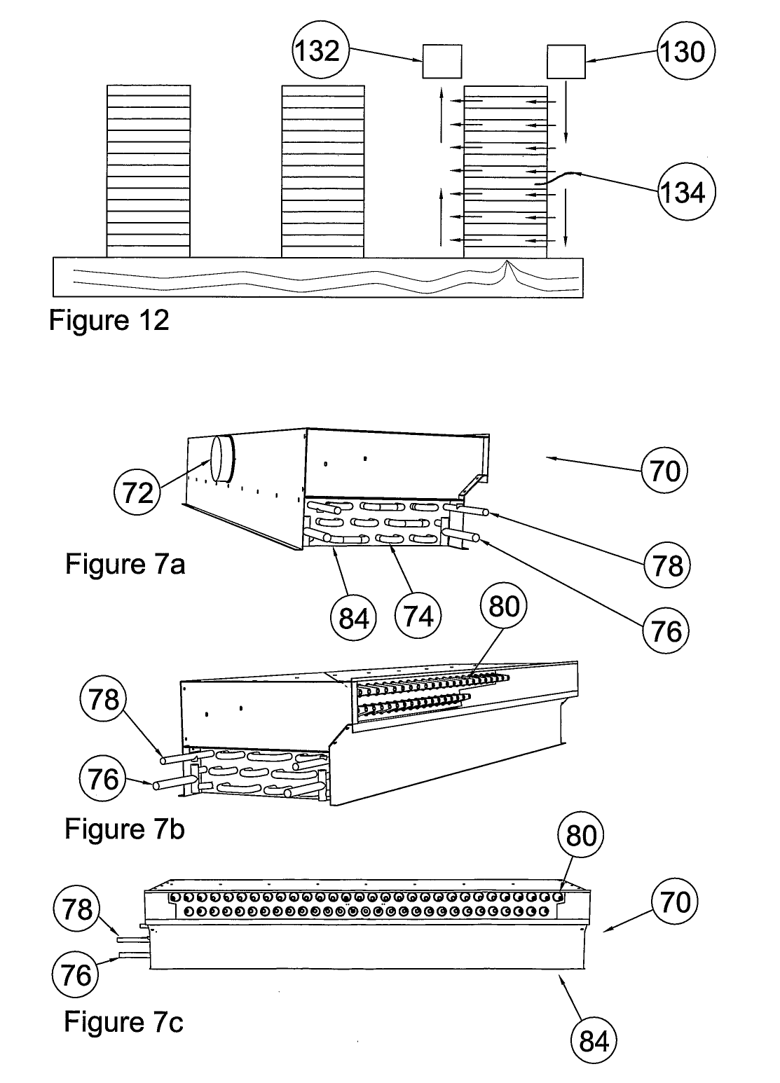

FIG. 7 shows schematically perspective views of an air conditioning unit which is a further embodiment:

FIG. 7a shows a front perspective view;

FIG. 7b shows an upper perspective view; and

FIG. 7c shows a side perspective view;

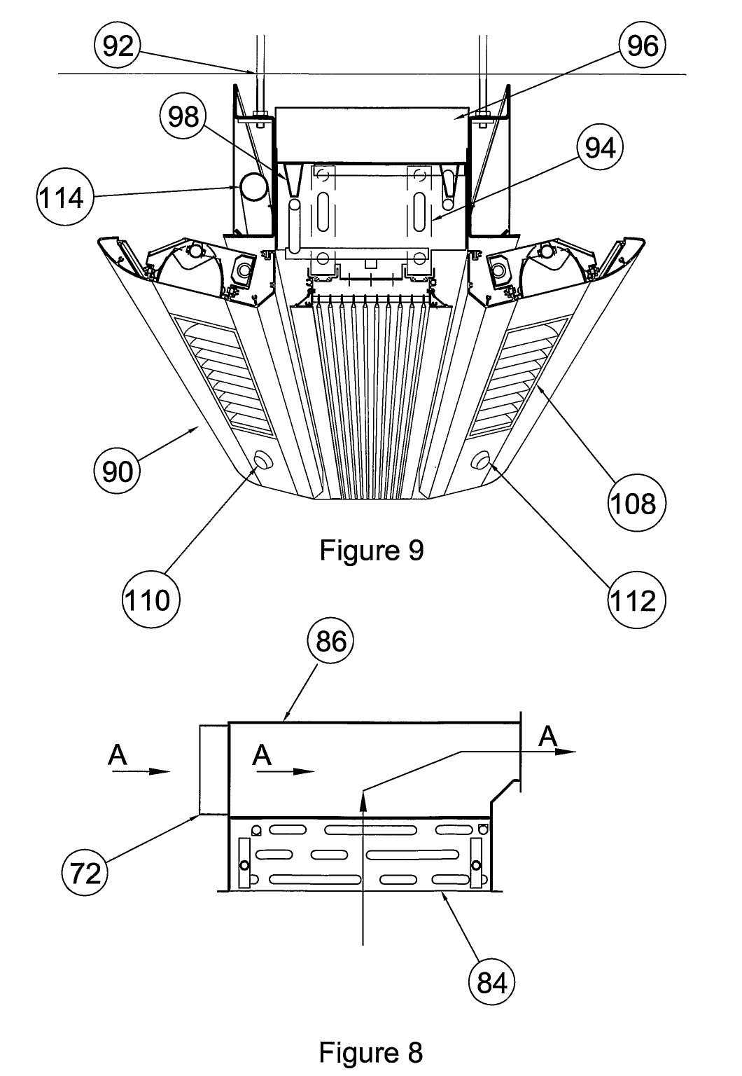

FIG. 8 shows schematically a front view of the unit of FIG. 7;

FIG. 9 shows schematically a front perspective view of building element which is a further embodiment;

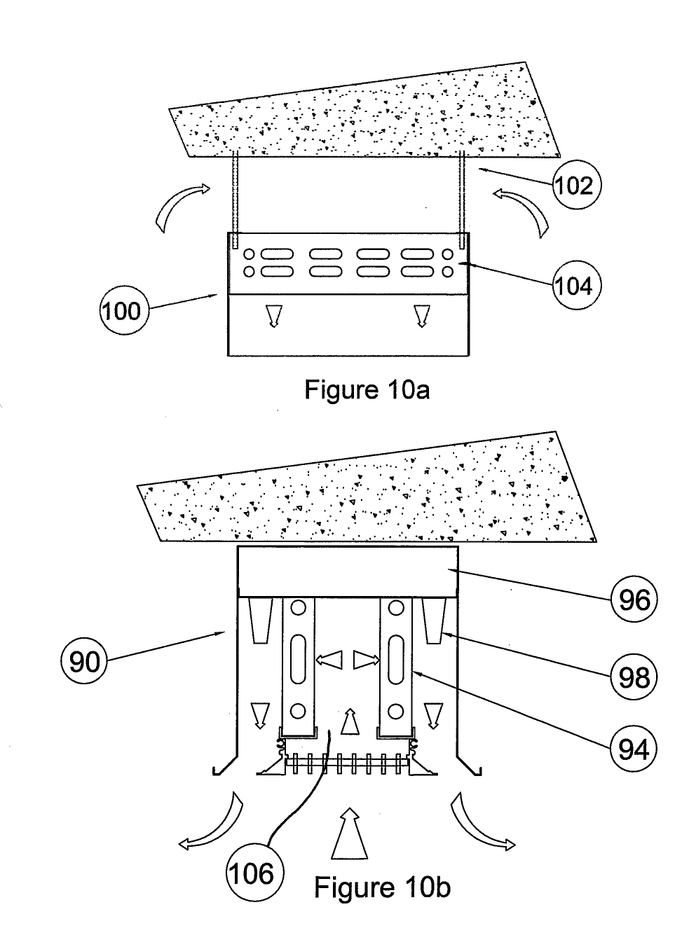

FIG. 10 shows schematically views of two embodiments of the building element shown in FIG. 9:

FIG. 10a shows a passive building element; and

FIG. 10b shows an active building element;

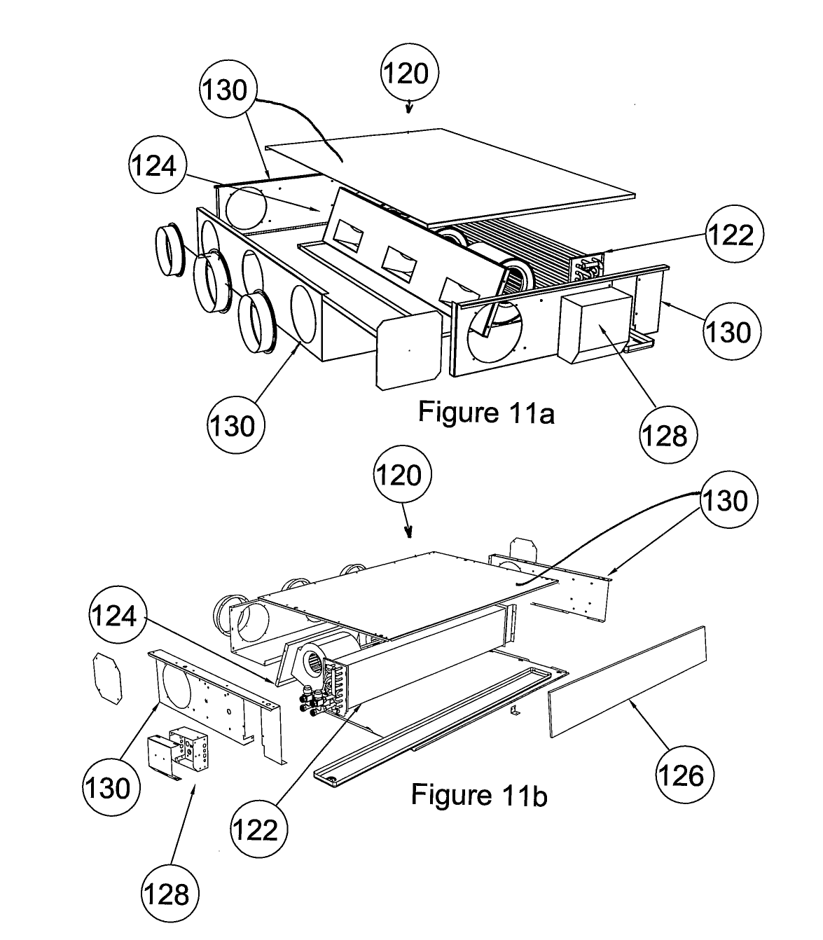

FIG. 11 shows schematically views of a fan cooled air conditioning unit which is a further embodiment;

FIG. 11a is an exploded perspective view; and

FIG. 11b is an exploded perspective view from a different angle; and

FIG. 12 shows schematically a further aspect of the invention.

A perspective view of three computer cabinets 10 containing blade servers and interspersed with three heat exchange cabinets 12 is shown in FIG. 1. Inlet pipes 14 and outlet pipes 16 can be seen at the lower end of each heat exchange cabinet 12. Each heat exchange cabinet 12 is positioned along one side of two computer cabinets 10 and occupies substantially all of that side.

As each computer cabinet 10 contains blade servers (or other similarly power hungry computer equipment), they generate a significant heat load—at current technology in the region of 15 kW to 20 kW per 900 mm×600 mm×1800 mm cabinet. Computer cabinets of other sizes may be pro-rated accordingly. The reason that cabinets having such high heat load can be placed so close together is that the cooling fluid flowing through the heat exchange cabinets 12 is highly efficient, being carbon dioxide.

The use of carbon dioxide as a secondary coolant fluid is known, being described in UK Patent No. 2 258 298. However, it has not been previously considered suitable for IT applications where air cooling has dominated ever since the field begun, as it is both electrically benign and intrinsically safe. Carbon dioxide is electrically benign but is not intrinsically safe, being fatal at concentrations of between 10% and 30%. As it must be used at very high pressures for effective cooling (50 Bar or above) leakage could be a real problem. The cooling media system incorporates leak detection and shut-off life safety measures; along with a rejection system to deal safely with the leaked substance.

FIG. 2 shows schematically the fluid flow around a primary heat transfer circuit 18 and a secondary heat transfer circuit 20. The primary heat transfer circuit 18 comprises a compressor 22, a primary condenser 24, an primary expansion device 26 and an evaporator 28. The heat transfer fluid used in the primary circuit is a volatile primary refrigerant of conventional composition.

The secondary heat transfer circuit 20 comprises a secondary condenser 30, which is cooled by the evaporator 28, a pump 32, which circulates fluid, a secondary expansion device 34 which reduces the heat transfer fluid to a design evaporating pressure and a heat exchanger 36, contained in a cabinet 12, which provides cooling to the surrounding air. The circulating fluid picks up heat from its surroundings in the heat exchanger and returns to the secondary condenser 30, thereby completing the circuit. Fans 38 circulate air through the heat exchange cabinet 12 to the computer cabinet 10.

The heat transfer fluid circulating in the secondary heat transfer circuit 20 is carbon dioxide under pressure. The advantages of using carbon dioxide are that it is readily available, inexpensive, and relatively non-toxic and non-polluting. Most importantly, however, when compared to systems which use non-volatile secondary heat transfer liquids, such as air, the mass flow of carbon dioxide required to produce the same cooling effect is substantially lower due to the high latent heat of carbon dioxide, when compared to the relatively low specific heat capacities of conventional non-volatile fluids cooling media such as air.

The carbon dioxide arrives at the heat exchanger in a volatile state at temperatures suitable to cool a surface area sufficiently below the room temperature to ensure that heat exchange takes place. Preferably the temperature is in the region of 14° C. in order to avoid condensation on the pipes and coil, in an environment having a temperature of 20° C. dry bulb, with a relative humidity of 45 to 55%. It is important to avoid condensation because of the risk that water will leak into adjacent electrical server equipment.

The working pressure of the system is generally in the region of 50 Bar, although it may be higher or lower.

A number of views of the heat exchange cabinet 12 are shown in FIG. 3. The cabinet 12 comprises the heat exchanger 36, which has an inlet 40 and an outlet 42, both disposed at the bottom end of the cabinet 12. Five fans 38, each having its own illuminated power supply indication switch 44 and fuse 46 are aligned along the rear panel of the cabinet, which faces away from the computer equipment in use. Air flow through the cabinet is indicated by the arrow on FIG. 3e, which shows that air flows from the computer equipment to the heat exchanger.

The fans are readily demountable, having an internal plug and socket arrangement for ease of replacement. Each fan may have a conventional power supply, an IEC 320 power inlet socket 48 being provided at the front of the cabinet. Alternatively, or additionally, the fans may use an uninterruptible power supply or UPS (not shown) in order to ensure continuity of operation in the event of a mains power failure. Typically the UPS will run for a period that is sufficient for the standby generators to become operational.

Threaded captive fasteners 50 are provided for mounting the heat exchange cabinet to the computer cabinet door.

The heat exchanger 36 is shown in more detail in FIG. 5. It is constructed from a copper and aluminium finned coil 52, which is pressure tested up to and above 100 Bar. It has interlaced coils with dual pipework to provide additional resilience in case of coil failure. A perforated panel 54 is sandwiched between the heat exchanger and the equipment cabinet in order to provide protection from damage.

Although the heat exchange cabinets 12 are shown in this embodiment as being positioned on the side of the computer cabinets 10, they may be positioned on top of the cabinets, below the cabinets or to the front or rear of the cabinets. Dissipation of large heat loads can be obtained by placing more than one heat exchange cabinet around the computer cabinets 10, for example the front and rear might both be covered. It is even possible to surround each computer cabinet 10 with heat exchange cabinets 12. Alternatively, or additionally, the heat exchange cabinets 12 may be placed inside the computer cabinets 10, where their effectiveness is greatly increased.

Another effective method of construction is to use a shrouded cabinet, whereby an inlet and an outlet shroud draws air around the computer cabinet, thereby reducing the amount of dead air.

By using such methods and apparatus it is possible to cool much larger loads than previous systems were capable of doing. Loads of up to 100 kW or more can be achieved by combinations of heat exchangers, whilst a single heat exchanger can provide loads of up to 20 kW even at the relatively early stage of development of this technology.

An embodiment of a second aspect is shown in FIG. 6. A computer cabinet 60 is shown which also functions as a heat exchange cabinet by virtue of having double skinned walls 62, front and rear doors 64 and shelving (not shown). Server equipment (not shown) may be stacked in the cabinet 60. The cabinet uses a volatile fluid, carbon dioxide, as a secondary refrigerant, in a similar circuit to that shown in FIG. 2, a heat exchanger (not shown) being incorporated into the double skinned walls of the cabinet. Inlet 66 and outlet 68 pipework tails receive and discharge carbon dioxide. The carbon dioxide is at a pressure of substantially 50 Bar and has a flow temperature of approximately 14° C.

The doors 64 have a perforated panel in order to promote the flow of air through the cabinet. The double skinned surface containing the heat exchanger may be any combination of the top, sides, bottom, shelving, front door, or rear door of the cabinet.

The cooling capacity is up to 20 kW per cabinet 60 of the standard size 900 mm long×600 mm wide×1800 mm high; for other sizes performance should be pro-rated up and down accordingly. The cabinet 60 may include integral distribution pipework.

FIGS. 7 and 8 show a third aspect of the invention—an air conditioning unit 70, which provides induction cooling. The unit 70 comprises an air inlet 72, a heat exchanger 74 having an inlet pipe 76 and an outlet pipe 78 and a plurality of induction nozzles 80.

The direction of air flow through the unit is shown in FIG. 8 by arrows A. Fresh air is drawn in through the air inlet 72 and mixes with recirculated air which is drawn in through a base 84 of the unit 70, through the heat exchanger 74. The fresh air mixes with the cooled recirculated air in a chamber 86 above the heat exchanger, and is discharged through the induction nozzles 80.

The unit 70 incorporates carbon dioxide as a secondary volatile refrigerant. The carbon dioxide is at a pressure of approximately 50 Bar providing a flow temperature of approximately 14° C. The air induction nozzles 80 operate at a pressure of approximately 80 Pa static pressure. The heat exchanger 74 comprises copper pipework and aluminium fins and may be designed to run “wet” with surface condensation or “dry” without condensation. The cooling capacity is up to 20 kW per unit 70.

The unit 70 may be mounted in the floor, ceiling, or walls of a room. The floor mounted solution is suitable for pedestrian and equipment cabinet traffic.

A fourth aspect of the invention, a building element 90 is shown in FIGS. 9 and 10. The building element 90 is a beam which carries a variety of building services, and is aesthetically tailored to suit individual buildings. The beam 90 is ceiling mounted using a uni-strut support 92. Cooling is provided through heat exchangers 94 which circulate air through a primary air duct 96 and induction nozzles 98 as shown in FIG. 10.

The heat exchangers 94 incorporate carbon dioxide as a secondary volatile refrigerant, using a heat transfer system similar to that shown in FIG. 2. The carbon dioxide will be at a pressure of approximately 50 Bar providing a flow temperature of approximately 14° C. The chilled beam technology may use a passive, as shown in FIG. 10a or an active variant, as shown in FIGS. 9 and 10b.

The passive variant 100 relies on convection. Hot air rises to the ceiling and is drawn into the beam through perforated panels 102 which make up its side walls. The air passes through a heat exchanger 104, is cooled and sinks, thus assuring the continuous flow of air through the beam. The capacity of the passive solution is up to 600 W/m. The active variant 90, shown in FIGS. 9 and 10b incorporates induction jets 98 operating at a pressure of up to 150 Pa static pressure. Air is drawn up through a central passage 106 in the beam 90, passes through the heat exchangers 94 and is mixed with air from the primary air duct 96, which is drawn down through induction jets 98. The cooled air sinks, promoting the flow through of air. The capacity of the active variant is up to 800 W/m.

The beam 90 may be a multi service beam incorporating other services including, but not limited to, lighting 108 and lighting control, PA/VA (public address/voice alarm) speakers 110, PIR (passive infrared) detectors 112, sprinklers 114, plasma screens, and power cables.

FIG. 11 shows a fifth aspect of the invention, a fan cooled air conditioning unit 120. The unit 120 comprises a heat exchanger 122, a plurality of fans 124, a filter 126, and a control box 128 all mounted on a housing 130. The unit 120 incorporates carbon dioxide as a secondary volatile refrigerant, in a heat transfer circuit similar to that shown in FIG. 2. The carbon dioxide is at a pressure of approximately 50 Bar providing a flow temperature of approximately 14° C. The unit 120 is available as a cooling only or cooling and electric re-heat option, incorporating an electric heater (not shown). The capacity is up to 10 kW per unit 120.

The heat exchanger 122 is made from copper pipework and aluminium fins and may be designed to run “wet” with surface condensation or “dry” without condensation. The heat exchanger process is achieved as the integral fans 124 push or pull inlet air across the heat exchanger 122 which is then discharged from the unit 120. The inlet air may be entirely fresh air and/or recirculated air from the space below. The discharged air may be supplied, through ducted connections, on to air diffusers.

FIG. 12 shows a further embodiment of the invention, which comprises two passive chilled elements 130 132, of the type shown in FIG. 10a, but forming a box rather than an elongate beam and comprising integral fan units. A downflow box 130 is positioned substantially level with the top of a computer cabinet 134, along one of its sides, and an upflow box 132 is positioned substantially level with the top of the computer cabinet 134 along the opposite side.

Air from the down-flow box is propelled down by its integral fan, passes through the computer cabinet and is draw upwards by the integral fan in the upflow box. The upflow box also absorbs heat from the natural convection currents which develop in the region of computer equipment. The cooling capacity of the upflow box, operating on air of approximately 31° C. is around 7.5 kW, the cooling capacity of the upflow box, operating on air of approximately 25° C. is around 5 kw.

Any of the above embodiments which show integral fans could, alternatively or additionally, be connected to computer equipment through a ducted air system.

Each feature disclosed in this specification (which term includes the claims) and/or shown in the drawings may be incorporated in the invention independently of other disclosed and/or illustrated features.

Statements in this specification of the “objects of the invention” relate to preferred embodiments of the invention, but not necessarily to all embodiments of the invention falling within the claims.

The description of the invention with reference to the drawings is by way of example only.

The text of the abstract filed herewith is repeated here as part of the specification.

Computer cooling equipment for computer equipment comprises: a primary heat transfer circuit; a secondary heat transfer circuit containing a secondary heat transfer fluid, a secondary condenser cooled by the primary heat transfer circuit and a secondary evaporator for cooling the computer equipment; and is characterised in that the secondary heat transfer fluid is a volatile fluid. The secondary heat transfer fluid may be carbon dioxide. The cooling system is of particular use in power hungry applications such as cooling of computer servers, particularly of blade servers as it can produce a heat load dissipation of up to 100 kW, compared to 10 kW or less using conventional systems. Heat exchange cabinets, air conditioning systems and building elements using a secondary heat transfer fluid which is a volatile fluid are also disclosed.

1-81. (canceled)

82. Computer cooling apparatus comprising a heat transfer circuit for containing a heat transfer fluid, and an evaporator for cooling computer equipment, wherein the heat transfer fluid is a volatile fluid.

83. Computer cooling apparatus according to claim 82 in which the volatile fluid is carbon dioxide.

84. Computer cooling apparatus according to claim 82, further comprising a computer cabinet for containing computer equipment.

85. Computer cooling apparatus according to claim 84 in which the evaporator is positioned on any of the sides, the top or the bottom of the computer cabinet and/or the evaporator is positioned inside the computer cabinet.

86. Computer cooling apparatus according to claim 82 further comprising a heat exchange cabinet, wherein the evaporator is contained in the heat exchange cabinet.

87. Computer cooling apparatus according to claim 86 in which the heat exchange cabinet comprises a shroud positioned at its air inlet such that incoming air is drawn from an adjacent side of the computer cabinet to that on which the heat exchange cabinet is disposed, and/or in which the heat exchange cabinet comprises a shroud positioned at its air outlet such that outgoing air is expelled to an adjacent side of the computer cabinet to that on which the heat exchange cabinet is disposed.

88. Computer cooling apparatus according to claim 86 in which the heat exchange cabinet comprises a plurality of fans to draw air through the computer cabinet.

89. Computer cooling apparatus according to claim 86 in which the heat exchange cabinet comprises a perforated panel sandwiched between the secondary evaporator and the computer cabinet.

90. Computer cooling apparatus according to claim 82 in which the evaporator comprises a heat exchanger constructed of a copper and aluminium finned coil.

91. Computer cooling apparatus according to claim 82, wherein the computer equipment comprises a computer server and/or a blade server.

92. Computer cooling apparatus according to claim 82 in which the circuit is operable at 25 Bar to 75 Bar, preferably up to 50 Bar.

93. Computer cooling apparatus according to claim 83 in which the temperature of the carbon dioxide received at the evaporator is in the region of 0° C. to 30° C. preferably in the region of 12° C. to 16° C., preferably substantially 14° C.

94. Computer cooling apparatus according to claim 82 further comprising:
a primary heat transfer circuit;
wherein the heat transfer circuit comprises a secondary heat transfer circuit for containing the volatile fluid, and the condenser comprises a secondary condenser,
wherein the secondary condenser is arranged to be cooled by the primary heat transfer circuit.

95. A housing for computer equipment, the housing including a heat exchanger which is adapted to form part of a heat transfer circuit containing a heat transfer fluid, wherein the heat transfer fluid comprises a volatile fluid, preferably carbon dioxide.

96. A housing according to claim 95, the housing comprising a cabinet for computer equipment.

97. A housing according to claim 95 comprising an outer layer and an inner layer characterised in that a heat exchanger is disposed between the outer layer and the inner layer.

98. A housing according to claim 95 having a top, sides a bottom, shelving and a front or rear door, one or more of which comprise the outer layer and the inner layer.

99. A housing according to claim 95 having a cooling capacity of up to 20 Kw, preferably up to 50 kW, per 900 mm long per 600 mm wide×1800 mm high cabinet.

100. A method of cooling computer equipment comprising:
circulating a fluid through a heat transfer circuit to a heat exchanger which is disposed adjacent to the computer equipment, wherein the fluid is a volatile fluid, preferably carbon dioxide.

101. Apparatus comprising a heat exchanger which forms part of a heat transfer circuit for a heat transfer fluid, wherein
a. the apparatus comprises an air conditioning unit including an air inlet, and an air outlet comprising an induction jet having a plurality of nozzles, or
b. the apparatus comprises a building element comprising an air inlet, an air outlet and an air duct, or
c. the apparatus comprises an air conditioning unit including a plurality of fans, or
d. the apparatus comprises a cooling unit for cooling electrical equipment, preferably for cooling computer equipment wherein the heat transfer fluid comprises a volatile fluid, preferably carbon dioxide.

102. Apparatus according to claim 101 wherein the heat exchanger is adapted to form part of a secondary heat transfer circuit.

103. Apparatus according to claim 101 operable at a pressure of up to 50 Bar, preferably up to 75 Bar.

104. Apparatus according to claim 101 characterised in that the temperature of the volatile fluid is in the region of 0 to 30° C., conveniently in the region of 12 to 16° C., preferably 14° C.

105. Apparatus according to claim 101 including an induction jet, in which the induction jet operates at a static pressure of in the region of 30 to 200 Pa, conveniently in the region of 50 to 100 Pa, preferably substantially 80 Pa.

106. Apparatus according to claim 101 including a building element including an elongate beam.

107. Apparatus according to claim 101 comprising a building element including a housing for building services such as lighting, lighting control, public address/voice alarm speakers, passive infrared detectors, sprinklers, plasma screens, power cables, and/or a heater.
